(19) United States
(12) Patent Application Publication
(10) Pub. No.: US 2025/0241172 A1
(43) Pub. Date: Jul. 24, 2025

(54) DISPLAY PANEL AND DISPLAY APPARATUS

(71) Applicants: Yunnan Invensight Optoelectronics Technology Co., Ltd., Kunming (CN); BOE Technology Group Co., Ltd., Beijing (CN)

(72) Inventors: Junbo WEI, Beijing (CN); Qingshan SHAN, Beijing (CN); Pengcheng LU, Beijing (CN); Shengji YANG, Beijing (CN); Yinhu HUANG, Beijing (CN); Yuanlan TIAN, Beijing (CN); Dacheng ZHANG, Beijing (CN)

(21) Appl. No.: 18/697,781

(22) PCT Filed: Aug. 31, 2023
(86) PCT No.: PCT/CN2023/116132

§ 371 Date: Apr. 2, 2024

(51) Int. Cl. H10K 59/80; H10K 59/122; H10K 59/38

(52) U.S. Cl. CPC H10K 59/8722; H10K 59/122; H10K 59/38; H10K 59/873; H10K 59/8792

(57) ABSTRACT

The present disclosure provides a display panel and a display apparatus, including: a display substrate, having a display region and a peripheral region around the display region; a first dam adhesive on a side of a light-emitting surface of the display substrate; where the first dam adhesive is arranged in the peripheral region and surrounds the display region; where a first outer circular arc of smooth transition is formed between outer adjacent side edges of the first dam adhesive relative to a center of the display region; and a cover plate on the side of the light-emitting surface of the display substrate, where the cover plate is bonded to the display substrate through the first dam adhesive.

The present disclosure is a national phase entry under 35 U.S.C § 371 of International Application No. PCT/CN2023/116132, filed Aug. 31, 2023, the entire content of which is incorporated herein by reference.

### TECHNICAL FIELD

The present disclosure relates to the field of a display technology, and in particular, relates to a display panel and a display apparatus.

### BACKGROUND

Micro-OLED is a new type of organic light-emitting diode (OLED) display apparatus with a silicon substrate as the substrate. The silicon-based OLED has the characteristics of the small size and high resolution, and is made by the mature integrated circuit complementary metal oxide semiconductor (CMOS) process, realizing active addressing of pixels. The silicon-based OLED adopts multiple circuits such as the timer control register (TCON) and over-current protection (OCP) circuit, and realizes lightweight. The silicon-based OLED is widely used in the field of near-eye display, virtual reality and augmented reality, especially in AR/VR head-mounted display apparatus.

### SUMMARY

Embodiments of the present disclosure provide a display panel and a display apparatus, and the specific solutions are as follows.

Embodiments of the present disclosure provides a display panel, including:
a display substrate, having a display region and a peripheral region around the display region;
a first dam adhesive on a side of a light-emitting surface of the display substrate; where the first dam adhesive is arranged in the peripheral region and surrounds the display region; where a first outer circular arc of smooth transition is formed between outer adjacent side edges of the first dam adhesive relative to a center of the display region; and a cover plate on the side of the light-emitting surface of the display substrate, where the cover plate is bonded to the display substrate through the first dam adhesive.

Optionally, in specific implementation, in the above display panel provided by the embodiments of the present disclosure, a first inner circular arc of smooth transition is formed between inner adjacent side edges of the first dam adhesive relative to the center of the display region.

Optionally, in specific implementation, in the above display panel provided by the embodiments of the present disclosure, a curvature of the first outer circular arc is greater than a curvature of the first inner circular arc.

Optionally, in specific implementation, in the above display panel provided by the embodiments of the present disclosure, an arc length of the first outer circular arc is greater than an arc length of the first inner circular arc.

Optionally, in specific implementation, in the above display panel provided by the embodiments of the present disclosure, a roughness of an inner surface of the first dam adhesive close to the display region is greater than a roughness of an outer surface of the first dam adhesive.

Optionally, in specific implementation, in the above display panel provided by the embodiments of the present disclosure, the peripheral region includes a binding region at a side of the display region; and an end of a side edge of the display region close to the binding region is substantially flush with an end of a flat side edge of the first dam adhesive close to the binding region.

Optionally, in specific implementation, in the above display panel provided by the embodiments of the present disclosure, the first dam adhesive includes: a first structure close to the binding region, a second structure opposite to the first structure, and a third structure and a fourth structure connecting the first structure and the second structure and disposed opposite to each other;

a width of the first structure is greater than or equal to a width of the second structure, the width of the second structure is greater than a width of the third structure, and a width of the fourth structure is equal to the width of the third structure.

Optionally, in specific implementation, in the above display panel provided by the embodiments of the present disclosure, the width of the first structure is within a range of 250 μm to 800 μm, the width of the second structure is within a range of 350 μm to 800 μm, and the width of the third structure is within a range of 200 μm to 350 μm.

Optionally, in specific implementation, the above display panel provided by the embodiments of the present disclosure further includes a second dam adhesive in the peripheral region. The second dam adhesive is on a same layer as the first dam adhesive, and the second dam adhesive is spaced apart from and surrounds the first dam adhesive.

Optionally, in specific implementation, in the above display panel provided by the embodiments of the present disclosure, a second outer circular arc of smooth transition is formed between outer adjacent side edges of the second dam adhesive relative to the center of the display region.

Optionally, in specific implementation, in the above display panel provided by the embodiments of the present disclosure, a second inner circular arc of smooth transition is formed between inner adjacent side edges of the second dam adhesive relative to the center of the display region.

Optionally, in specific implementation, in the above display panel provided by the embodiment of the present disclosure, a curvature of the second outer circular arc is greater than a curvature of the second inner circular arc, and the curvature of the second inner circular arc is greater than the curvature of the first outer circular arc.

Optionally, in specific implementation, in the above display panel provided by the embodiments of the present disclosure, an arc length of the second outer circular arc is greater than an arc length of the second inner circular arc, and the arc length of the second inner circular arc is greater than the arc length of the first outer circular arc.

Optionally, in specific implementation, in the above display panel provided by the embodiment of the present disclosure, the second dam adhesive is at a side of the first dam adhesive away from the display region; and a width of the second dam adhesive is greater than the width of the first dam adhesive at same positions of the first dam adhesive and the second dam adhesive.

Optionally, in specific implementation, in the above display panel provided by the embodiments of the present disclosure, the width of the first dam adhesive is greater than a distance between the first dam adhesive and the second dam adhesive.

Optionally, in specific implementation, in the above display panel provided by the embodiments of the present disclosure, the width of the first dam adhesive is within a range of 350 μm to 550 μm, the width of the second dam adhesive is within a range of 400 μm to 600 μm, and the distance between the first dam adhesive and the second dam adhesive is within a range of 100 μm to 500 μm.

Optionally, in specific implementation, in the above display panel provided by the embodiments of the present disclosure, a distance between an outer edge of the second dam adhesive and an edge of the display substrate is within a range of 100 μm to 300 μm.

Optionally, in specific implementation, in the above display panel provided by the embodiments of the present disclosure, a first concave-convex structure is provided on an inner surface of the first dam adhesive close to the display region; and a second concave-convex structure is provided on an inner surface of the second dam adhesive close to the display region.

Optionally, in specific implementation, in the above display panel provided by the embodiments of the present disclosure, a width of a concave position in the first concave-convex structure is greater than a width of a concave position in the second concave-convex structure, and a width of a convex position in the first concave-convex structure is greater than a width of a convex position in the second concave-convex structure.

Optionally, in specific implementation, in the above display panel provided by the embodiments of the present disclosure, the width of the concave position and the width of the convex position in the first concave-convex structure are within a range of 50 μm to 80 μm, and the width of the concave position and the width of the convex position in the second concave-convex structure are within a range of 30 μm to 60 μm.

Optionally, in specific implementation, the above display panel provided by the embodiments of the present disclosure further includes a filler adhesive on an inner side of the first dam adhesive, where the filler adhesive is in direct contact with the first dam adhesive.

Optionally, in specific implementation, the above display panel provided by the embodiments of the present disclosure further includes a filler adhesive between the first dam adhesive and the second dam adhesive.

Optionally, in specific implementation, in the above display panel provided by the embodiments of the present disclosure, a height of the first dam adhesive is same as a height of the second dam adhesive.

Optionally, in specific implementation, in the above display panel provided by the embodiments of the present disclosure, the peripheral region further includes a cathode ring region between the binding region and the display region, and an orthographic projection of the first dam adhesive on the display substrate covers the cathode ring region.

Optionally, in specific implementation, in the above display panel provided by the embodiments of the present disclosure, the display substrate includes: a substrate, a light-emitting device layer between the substrate and the first dam adhesive, a first encapsulation structure between the light-emitting device layer and the first dam adhesive, a color film layer between the first encapsulation structure and the first dam adhesive, and a second encapsulation structure between the color film layer and the first dam adhesive;
the color film layer includes: a plurality of color resists of different colors disposed in the display region and distributed in an array, and at least one layer of shielding structures with a planar structure in the peripheral region; and each layer of the shielding structures is fabricated in synchronization with one of the plurality of color resists.

Optionally, in specific implementation, in the above display panel provided by the embodiments of the present disclosure, the display substrate further includes: a first planarization layer between the first encapsulation structure and the color film layer, a second planarization layer between the second encapsulation structure and the first dam adhesive, a third planarization layer between the second planarization layer and the first dam adhesive, a plurality of micro lenses between the third planarization layer and the first dam adhesive, and a protective layer between the plurality of micro lenses and the first dam adhesive.

Optionally, in specific implementation, in the above display panel provided by the embodiment of the present disclosure, the substrate is a silicon substrate.

Optionally, in specific implementation, in the above display panel provided by the embodiments of the present disclosure, the light-emitting device layer includes an anode layer, a pixel defining layer, a light-emitting function layer, and a cathode layer disposed in sequence; and the display substrate further includes a driving circuit for applying a driving voltage to the anode layer and the cathode layer, where the driving circuit is independent of the substrate or the driving circuit is integrated in the substrate.

Correspondingly, an embodiment of the present disclosure further provides a display apparatus, including the above any display panel provided by the embodiments of the present disclosure.

### BRIEF DESCRIPTION OF FIGURES

FIG. 1 is a schematic diagram of a planar structure of a display panel provided in the related art.

FIG. 2 is a schematic planar view of a display panel provided by an embodiment of the present disclosure.

FIG. 3 is a schematic diagram of a cross-section along the CC′ direction in FIG. 2.

FIG. 4 is a schematic diagram of an actual product corresponding to the upper left corner of a first dam adhesive in FIG. 2.

FIG. 5 is a schematic diagram of an actual product corresponding to the upper right corner of a first dam adhesive in FIG. 2.

FIG. 6 is a schematic diagram of an actual product corresponding to the lower right corner of a first dam adhesive in FIG. 2.

FIG. 7 is another schematic planar view of a display panel provided by an embodiment of the present disclosure.

FIG. 8 is another schematic planar view of a display panel provided by an embodiment of the present disclosure.

FIG. 9 is a schematic diagram of a cross-section along the CC′ direction in FIG. 7 and FIG. 8.

FIG. 10 is another schematic planar view of a display panel provided by an embodiment of the present disclosure.

FIG. 11 is a schematic diagram of a local structure of the first dam adhesive in FIG. 7, FIG. 8 and FIG. 10.

FIG. 12 is a schematic diagram of a local structure of the second dam adhesive in FIG. 7, FIG. 8 and FIG. 10.

FIG. 13 is another schematic structural diagram of a display panel provided by an embodiment of the present disclosure.

FIG. 14 is a schematic planar view of some structures in FIG. 3 and FIG. 9.

FIG. 15 is a three-dimensional schematic diagram of some structures in a display panel provided by an embodiment of the present disclosure.

### DETAILED DESCRIPTION

In order to make the objectives, technical solutions and advantages of the present disclosure clearer, the display panel and display apparatus provided in the present disclosure will be further described in detail below in combination with the drawings. Obviously, the described embodiments are only some embodiments of the present disclosure and not all of the embodiments. Based on the embodiments in the present disclosure, all other embodiments obtained by a person of ordinary skill in the art without creative labor fall within the scope of protection of the present disclosure.

The shapes and sizes of the components in the accompanying drawings do not reflect the true proportion of the display panel, and are intended only to schematically illustrate the present disclosure.

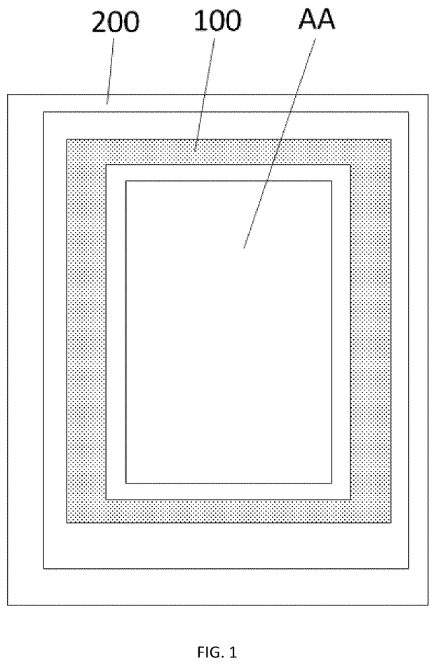

The silicon-based OLED display panel includes a display substrate and a cover plate that cover the display substrate, the display panel includes a display region and a peripheral region disposed around the display region, and the cover plate and the display substrate are generally bonded to each other through the dam adhesive in the peripheral region. However, the silicon-based OLED display panel in the related art, as shown in FIG. 1 which is a schematic planar diagram of the display panel, adopts a single layer of the dam adhesive 100 disposed around the display region AA to bond the display substrate 200 and the cover plate. On the one hand, the single layer of the dam adhesive 100 does not have sufficient connecting strength, which causes the cover plate to fall off, and is prone to cause the bubble problem; on the other hand, four corners of the dam adhesive 100 are designed at approximately right angles, widths of the corners are small, and stress of the corners is large, which is prone to cause peeling or whitening at the edges of the dam adhesive 100. With respect to the design of four corners of the dam adhesive 100 at approximately right angles, the outer corners of the dam adhesive 100 are designed as circular arcs that outwardly protrude in the related art, but the connection position between the circular arc and the side edge is not smooth, i.e., there is still a tip at the connection position between the circular arc and the side edge, which still leads to the problem of peeling or static electricity accumulation of the dam adhesive.

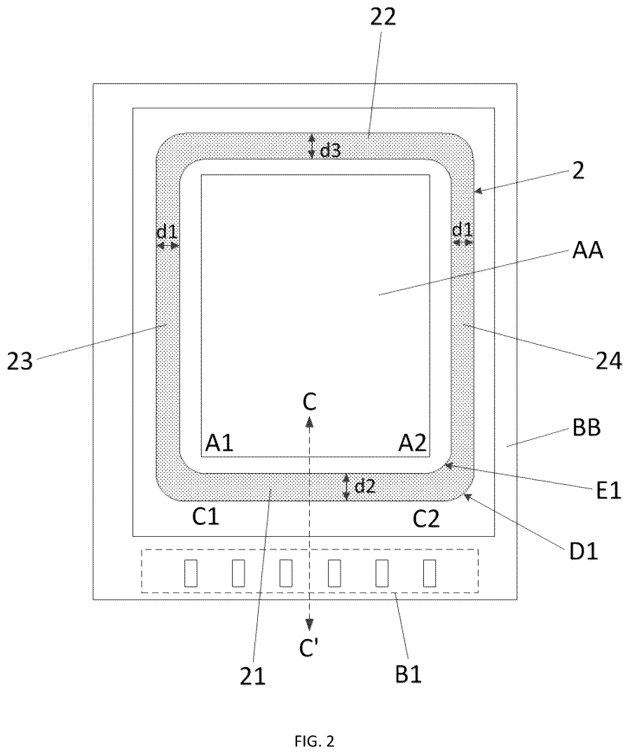

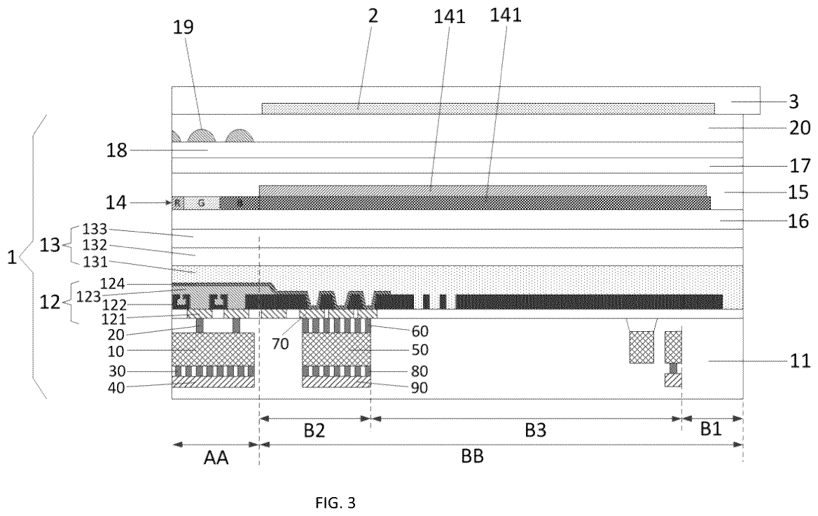

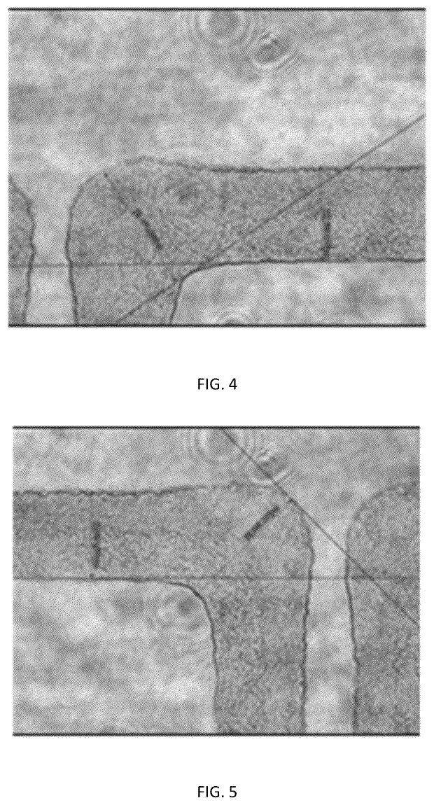

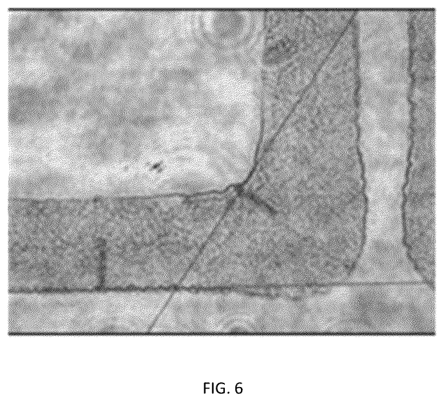

In view of this, embodiments of the present disclosure provide a display panel as shown in FIG. 2 to FIG. 6. FIG. 2 is a schematic planar diagram of the display panel, FIG. 3 is a schematic diagram of a cross-section along the direction of CC′ in FIG. 2, FIG. 4 is a schematic diagram of an actual product corresponding to the upper left corner of the first dam adhesive 2 in FIG. 2, FIG. 5 is a schematic diagram of an actual product corresponding to the upper right corner of the first dam adhesive 2 in FIG. 2, and FIG. 6 is a schematic diagram of an actual product corresponding to the lower right corner of the first dam adhesive 2 in FIG. 2. The display panel includes:

a display substrate 1, having a display region AA and a peripheral region BB around the display region AA;

a first dam adhesive 2 on a side of a light-emitting surface of the display substrate 1, where the first dam adhesive 2 is arranged in the peripheral region BB and surrounds the display region AA; where a first outer circular arc D1 of smooth transition is formed between outer adjacent side edges of the first dam adhesive 2 relative to a center of the display region AA; and a cover plate 3 on the side of the light-emitting surface of the display substrate 1, where the cover plate 3 is bonded to the display substrate 1 through the first dam adhesive 2.

The above display panel provided by the embodiments of the present disclosure, a first outer circular arc of smooth transition is formed between outer adjacent side edges of the first dam adhesive relative to a center of the display region, so that the curvature of the connection position between the first outer circular arc and the side edge is consistent with the curvature of the first outer circular arc, preventing the problem of static electricity accumulation due to the existence of a tip at the connection position between the first outer circular arc and the side edge. In addition, the first outer circular arc can increase the width of the corner, reduce stress of the corner, and mitigate the problem that the edge of the first dam adhesive is prone to peeling or whitening, thereby improving the stability of the display panel, enhancing the competitive advantage of the product, and increasing the yield of the product.

In specific implementation, in the above display panel provided in the embodiments of the present disclosure, as shown in FIG. 2 and FIG. 4-FIG. 6, a first inner circular arc E1 of smooth transition is formed between inner adjacent side edges of the first dam adhesive 2 relative to the center of the display region AA. In this way, the curvature of the connection position between the first inner circular arc E1 and the side edge is consistent with the curvature of the first inner circular arc E1, preventing the problem of static electricity accumulation due to the existence of a tip at the connection position between the first inner circular arc E1 and the side edge. In addition, the first inner circular arc E1 can increase the width of the corner, reduce stress of the corner, and further mitigate the problem of peeling due to warping on the inner side of the first dam adhesive 2, so as to further improve the stability of the display panel, enhance the competitive advantage of the product, and increase the yield of the product.

In specific implementation, in the above display panel provided by the embodiments of the present disclosure, as shown in FIG. 2 and FIG. 4-FIG. 6, the curvature of the first outer circular arc D1 is greater than the curvature of the first inner circular arc E1. This can minimize the area occupied by the first dam adhesive 2 in the peripheral region BB as much as possible, which is conducive to realizing the narrow bezel design of the display panel.

In specific implementation, in the above display panel provided by the embodiments of the present disclosure, as shown in FIG. 2 and FIG. 4-FIG. 6, an arc length of the first outer circular arc D1 is greater than an arc length of the first inner circular arc E1, which can also reduce the area occupied by the first dam adhesive 2 in the peripheral region BB, and realize the narrow bezel design of the display panel.

In specific implementation, before the display substrate is bonded to the cover plate, a frame-shaped dam adhesive is generally coated on the cover plate first, then the filler adhesive is coated within the dam adhesive frame, then the display substrate is aligned with the cover plate, and finally the dam adhesive and the filler adhesive are cured. In order to make the bonding between the dam adhesive and the filler adhesive better, in the above display panel provided by the embodiments of the present disclosure, as shown in FIG. 2 and FIG. 4-FIG. 6, a roughness of an inner surface of the first dam adhesive 2 close to the display region AA is greater than a roughness of an outer surface of the first dam adhesive. This allows the inner surface of the first dam adhesive 2 close to the display region AA to be tightly adhered to the filler adhesive, improving the encapsulation stability of the display panel.

In specific implementation, in the above display panel provided by the embodiments of the present disclosure, as shown in FIG. 2, the peripheral region BB includes a binding region B1 located at a side of the display region AA, and ends (A1 and A2) of a side edge of the display region AA close to the binding region B1 are substantially flush with ends (C1 and C2) of a flat side edge of the first dam adhesive 2 close to the binding region B1, that is, A1 is flush with C1, and A2 is flush with C2, which can ensure the flatness of the film layer of the binding region B1 and improve the stability of the display panel.

In specific implementation, in the above display panel provided by an embodiment of the present disclosure, as shown in FIG. 2, the first dam adhesive 2 includes: a first structure 21 close to the binding region B1, a second structure 22 opposite to the first structure 21, and a third structure 23 and a fourth structure 24 connecting the first structure 21 and the second structure 22 and disposed opposite to each other. A width d2 of the first structure 21 is greater than or equal to a width d3 of the second structure 22, the width d3 of the second structure 22 is greater than a width d1 of the third structure 23, and a width of the fourth structure 24 is equal to a width d1 of the third structure 23, that is, the width of the fourth structure 24 is also d1. Since the binding region B1 needs to be bent to the back of the display panel, stress will be generated during bending, which may easily cause peeling at the edge of the first structure 21. Therefore, the widths of various structures of the first dam adhesive 2 are designed to be d2≥d3>d1, that is, the first structure 21 close to the binding region B1 is designed to be wider, which can make it less likely that peeling occurs at the edge of the first structure 21, thereby making the bonding between the display substrate 1 and the cover plate 3 more solid and improving the stability of the product.

Optionally, in the above display panel provided by the embodiments of the present disclosure, as shown in FIG. 2, the width d2 of the first structure 21 is within the range of 250 μm to 800 μm, the width d3 of the second structure 22 is within the range of 350 μm to 800 μm, and the widths d1 of the third structure 23 and the fourth structure 24 are within the range of 200 μm to 350 μm. The range is designed, so that, on the one hand, the bonding between the display substrate 1 and the cover plate 3 can be more firm, and on the other hand, the width of the peripheral region BB will not be too large, thereby realizing the narrow bezel design.

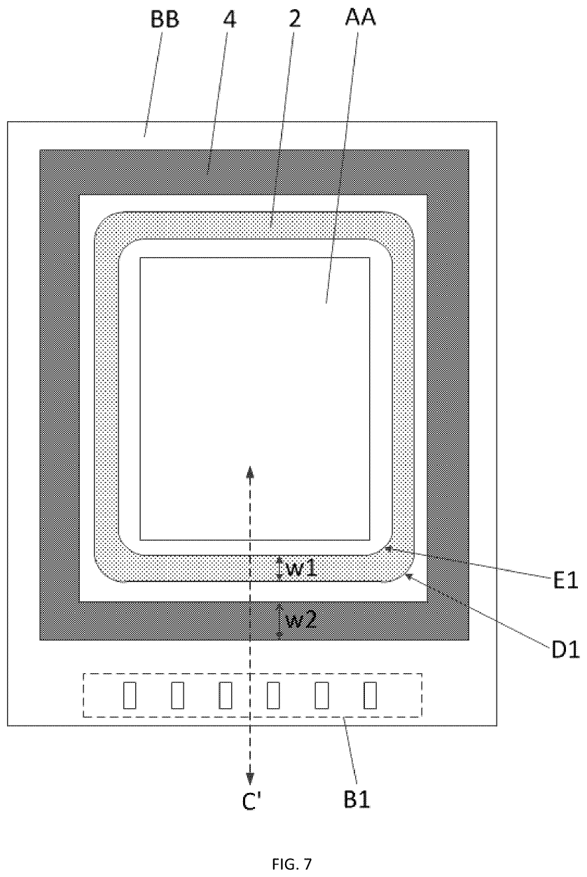

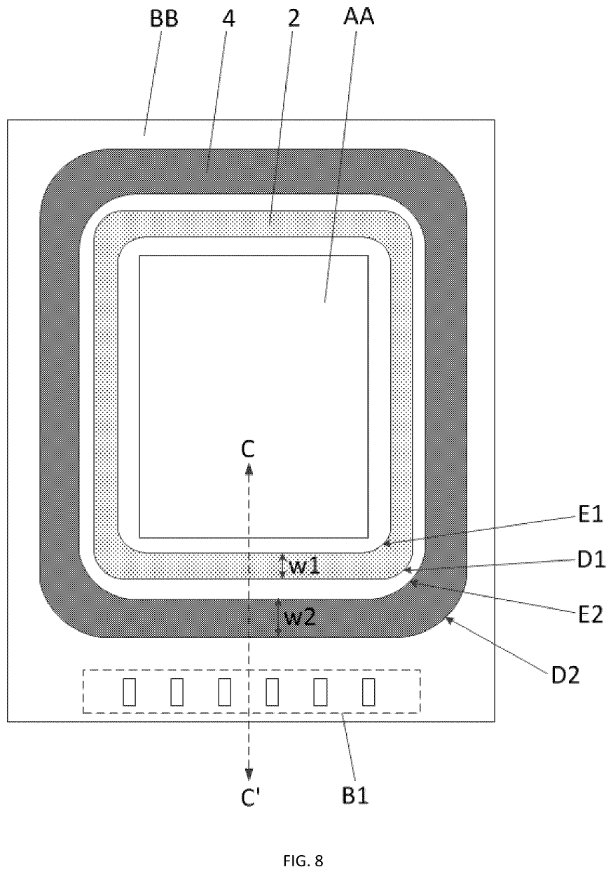

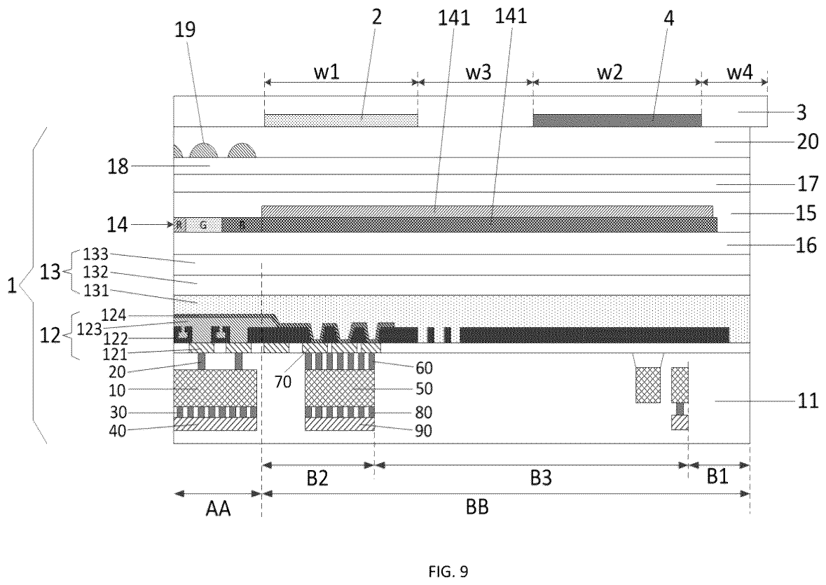

In specific implementation, in the above display panel provided by the embodiments of the present disclosure, as shown in FIG. 7-FIG. 9, FIGS. 7-8 are two other schematic planar views of the display panel provided by the present disclosure, and FIG. 9 is a schematic diagram of a cross-section along the direction CC′ in FIGS. 7-8. The display panel further includes a second dam adhesive 4 in the peripheral region BB, the second dam adhesive 4 is on the same layer as the first dam adhesive 2, and the second dam adhesive 4 is spaced apart from and around the first dam adhesive 2. In this way, the design of the first dam adhesive 2 can reduce the stress at the corner to prevent edge peeling, and the second dam adhesive 4 is designed, so that the double-layer dam adhesive design is adopted between the display substrate 1 and the cover plate 3, and the bonding between the display substrate 1 and the cover plate 3 is more solid, preventing the cover plate 3 from falling off, so as to avoid the bubble problem. Moreover, the second dam adhesive 4 is spaced apart from the first dam adhesive 2, which can make the entry path of the external water vapor larger, thereby enhancing the encapsulation effect.

Optionally, in the above display panel provided by the embodiments of the present disclosure, as shown in FIG. 7, the outer corners of the second dam adhesive 4 may be the same as that in the related art, i.e., no circular arc design is made. In order to prevent static accumulation, peeling, or whitening problems from occurring at the edges of the second dam adhesive 4, as shown in FIG. 8, a second outer circular arc D2 of smooth transition is formed between outer adjacent side edges of the second dam adhesive 4 relative to the center of the display region AA. In this way, the curvature of the connection position between the second outer circular arc D2 and the side edge is consistent with the curvature of the second outer circular arc D2, preventing the problem of static electricity accumulation due to the existence of a tip at the connection position between the second outer circular arc D2 and the side edge. In addition, the second outer circular arc D2 can increase the corner width of the outer corner of the second dam adhesive 4, reduce stress of the corner, and mitigate the problem that the edge of the second dam adhesive 4 is prone to peeling or whitening, thereby further improving the stability of the display panel, enhancing the competitive advantage of the product, and increasing the yield of the product.

In specific implementation, in the above display panel provided by the embodiments of the present disclosure, as shown in FIG. 8, a second inner circular arc E2 of smooth transition is formed between inner adjacent side edges of the second dam adhesive 4 relative to the center of the display region AA. In this way, the curvature of the connection position between the second inner circular arc E2 and the side edge is consistent with the curvature of the second inner circular arc E2, preventing the problem of static electricity accumulation due to the existence of a tip at the connection position between the second inner circular arc E2 and the side edge. In addition, the second inner circular arc E2 can increase the width of the corner, reduce stress of the corner, and further mitigate the problem of peeling due to warping on the inner side of the second dam adhesive 4, thereby further improving the stability of the display panel, enhancing the competitive advantage of the product, and increasing the yield of the product.

In specific implementation, in the above display panel provided by the embodiments of the present disclosure, as shown in FIG. 8, the curvature of the second outer circular arc D2 is greater than the curvature of the second inner circular arc E2, and the curvature of the second inner circular arc E2 is greater than the curvature of the first outer circular arc D1. This can minimize the area occupied by the second dam adhesive 4 in the peripheral region BB as much as possible, which is conducive to realizing the narrow bezel design of the display panel.

In specific implementation, in the above display panel provided by an embodiment of the present disclosure, as shown in FIG. 8, an arc length of the second outer circular arc D2 is greater than an arc length of the second inner circular arc E2, and the arc length of the second inner circular arc E2 is greater than the arc length of the first outer circular arc D1. This can also reduce the area occupied by the second dam adhesive 4 in the peripheral region BB, and realize the narrow bezel design of the display panel.

In specific implementation, in the above display panel provided by the embodiments of the present disclosure, as shown in FIG. 7-FIG. 9, the second dam adhesive 4 is disposed at a side, away from the display region AA, of the first dam adhesive 2; and a width w2 of the second dam adhesive 4 is greater than the width w1 of the first dam adhesive 2 at same positions of the first dam adhesive 2 and the second dam adhesive 4, which can make the bonding between the display substrate 1 and the cover plate 3 in the peripheral region more firm, further improving the stability of the display panel.

In specific implementation, in the above display panel provided by the embodiments of the present disclosure, as shown in FIG. 7-FIG. 9, the width w1 of the first dam adhesive 2 is larger than a distance w3 between the first dam adhesive 2 and the second dam adhesive 4. In this way, an area of the dam adhesives in the peripheral region BB can be larger, further improving the firmness of the bonding between the display substrate 1 and the cover plate 3.

Optionally, in the above display panel provided by the embodiments of the present disclosure, as shown in FIG. 7-FIG. 9, the width w1 of the first dam adhesive 2 is within the range of 350 μm to 550 μm, the width w2 of the second dam adhesive 4 is within the range of 400 μm to 600 μm, and the distance w3 between the first dam adhesive 2 and the second dam adhesive 4 is within the range of 100 μm to 500 μm. The range is designed, so that the bonding between the display substrate 1 and the cover plate 3 is more firm and the width of the peripheral region BB is not too large.

Optionally, in the above display panel provided by the embodiments of the present disclosure, as shown in FIG. 7-FIG. 9, a distance w4 between the outer edge of the second dam adhesive 4 and an edge of the display substrate 1 is within the range of 100 μm to 300 μm. Since the display panel is obtained by cutting from a motherboard, the cutting line is generally located between the outer edge of the second dam adhesive 4 and the edge of the display substrate 1. By reserving a certain distance between the second dam adhesive 4 and the edge of the display substrate 1, the second dam adhesive 4 cannot be cut when cutting, and thus no warping problem caused by cutting will occur, thereby further improving the firmness of the bonding between the display substrate 1 and the cover plate 3.

In specific implementation, in the above display panel provided by the embodiments of the present disclosure, as shown in FIGS. 7-8, the widths of the second dam adhesive 4 at the upper, lower, left and right positions are designed differently, the width at the position close to the binding region B1 is the largest, the widths at the left and right positions are the same and the smallest, and the width at the position away from the binding region B1 is in the middle.

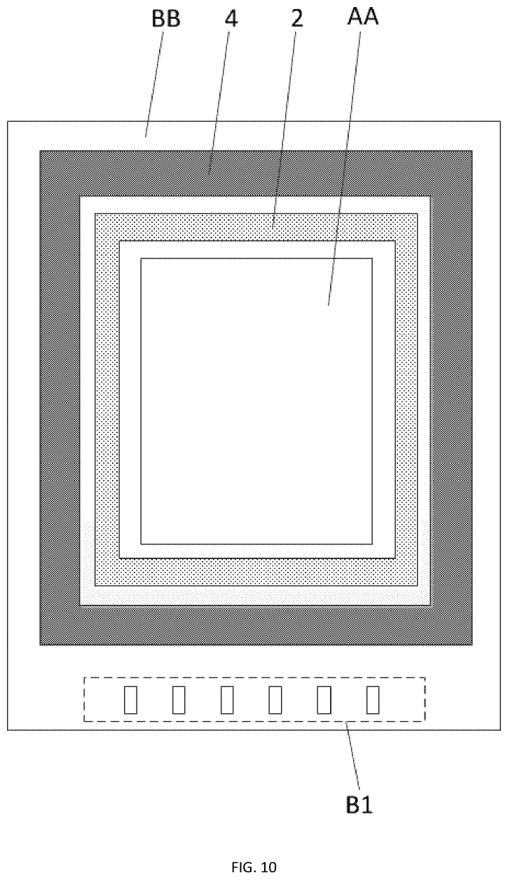

In specific implementation, in the above display panel provided by the embodiments of the present disclosure, as shown in FIG. 10, the display panel provided by the present disclosure adopts a double-layer dam adhesive structure with the second dam adhesive 4 set around the first dam adhesive 2, and the outer corners of the first dam adhesive 2 and the second dam adhesive 4 are not designed as circular arcs, which can also improve the firmness of the bonding between the display substrate 1 and the cover plate 3. Of course, the number of dam adhesive frames is not limited to two, but may also be three or more, and is designed as needed.

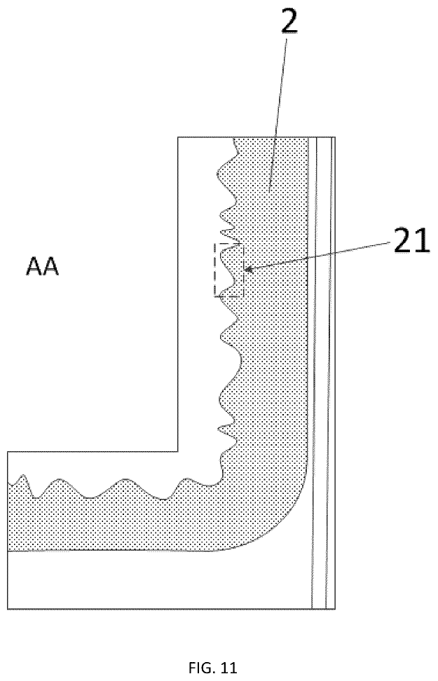

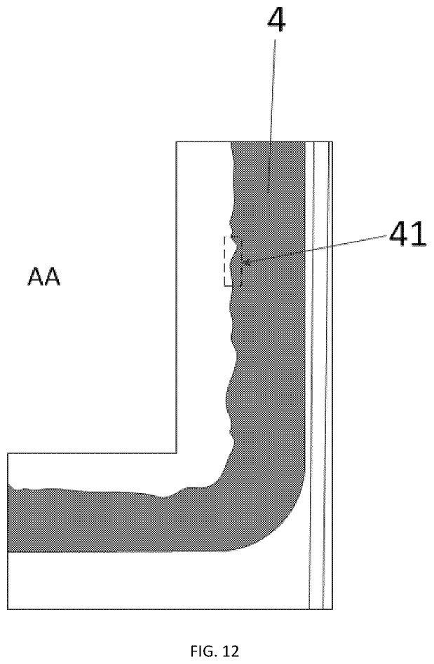

In specific implementation, before the display substrate is bonded to the cover plate, a frame-shaped dam adhesive is generally coated on the cover plate first, then the filler adhesive is coated within the dam adhesive frame, then the display substrate is aligned with the cover plate, and finally the dam adhesive and the filler adhesive are cured. In order to make the bonding between the dam adhesive and the filler adhesive better, in the above display panel provided by the embodiments of the present disclosure as shown in FIG. 11 and FIG. 12, FIG. 11 is a schematic diagram of a local structure of the first dam adhesive 2 in FIGS. 7-8 and FIG. 10, FIG. 12 is a schematic diagram of a local structure of the second dam adhesive 4 in FIGS. 7-8 and FIG. 10, a first concave-convex structure 21 is provided on an inner surface, close to the display region AA, of the first dam adhesive 2; and a second concave-convex structure 41 is provided on an inner surface, close to the display region AA, of the second dam adhesive 4. In this way, the first dam adhesive 2 and the second dam adhesive 4 have the better bonding with the filler adhesive, resulting in the better bonding performance.

In specific implementation, in the above display panel provided by the embodiments of the present disclosure, as shown in FIGS. 11-12, a width of a concave position in the first concave-convex structure 21 is greater than a width of a concave position in the second concave-convex structure 41, and a width of a convex position in the first concave-convex structure 21 is greater than a width of a convex position in the second concave-convex structure 41, i.e., the concavity and convexity in the first concave-convex structure 21 is more obvious. Since there is the more filler adhesive filled inside the first dam adhesive 2, the first concave-convex structure 21 may allow the filler adhesive to be filled more fully, resulting in the better bonding between the first dam adhesive 2 and the filler adhesive.

Optionally, in the above display panel provided by the embodiments of the present disclosure, as shown in FIGS. 11-12, the width of the concave position and the width of the convex position in the first concave-convex structure are within the range of 50 μm to 80 μm, and the width of the concave position and the width of the convex position in the second concave-convex structure are within the range of 30 μm to 60 μm.

In specific implementation, the above display panel provided by the embodiment of the present disclosure, as shown in FIG. 9 and FIGS. 11-12, further includes a filler adhesive (not shown) arranged at the inner side of the first dam adhesive 2, and the filler adhesive is in direct contact with the first dam adhesive 2. The filler adhesive is in direct contact with the first dam adhesive 2, which can ensure that the filler adhesive is filled sufficiently.

In specific implementation, the above display panel provided by the embodiments of the present disclosure, as shown in FIG. 9, further includes a filler adhesive (not shown) between the first dam adhesive 2 and the second dam adhesive 4, which can further ensure the sealing performance of the display panel. Of course, it is also possible not to fill the filler adhesive between the first dam adhesive 2 and the second dam adhesive 4.

In specific implementation, in order to ensure the firmness of the bonding between the display substrate and the cover plate and improve the sealing performance of the display panel, in the above display panel provided by the embodiments of the present disclosure, as shown in FIG. 9, a height of the first dam adhesive 2 is the same as a height of the second dam adhesive 4. Optionally, the height of the first dam adhesive 2 and the height of the second dam adhesive 4 are within the range of 5 μm to 10 μm.

In specific implementation, in the above display panel provided by the embodiments of the present disclosure, as shown in FIG. 3 and FIG. 9, the peripheral region BB further includes a cathode ring region B2 between the binding region B1 and the display region AA, and an orthographic projection of the first dam adhesive 2 on the display substrate 1 covers the cathode ring region B2. In this way, the first dam adhesive 2 can provide a shielding effect on the cathode ring region B2, and reduce the reflection from the cathode ring region B2, thereby improving the display uniformity of the peripheral region BB of the display panel.

In specific implementation, in the above display panel provided by the embodiments of the present disclosure, as shown in FIG. 3, the peripheral region BB further includes a metal wiring region B3 between the binding region B1 and the cathode ring region B2, and an orthographic projection of the first dam adhesive 2 on the display substrate 1 covers the metal wiring region B3. In this way, the first dam adhesive 2 can provide a shielding effect on the metal wiring region B3, and reduce the reflection from the metal wiring region B3, thereby further improving the display uniformity of the peripheral region BB of the display panel.

In specific implementation, in the above display panel provided by the embodiments of the present disclosure, as shown in FIG. 9, the peripheral region BB further includes a metal wiring region B3 between the binding region B1 and the cathode ring region B2, and an orthographic projection of the second dam adhesive 4 on the display substrate 1 covers a portion of the metal wiring region B3. In this way, the second dam adhesive 4 can provide a shielding effect on the portion of the metal wiring region B3, and reduce the reflection from the metal wiring region B3, thereby further improving the display uniformity of the peripheral region BB of the display panel.

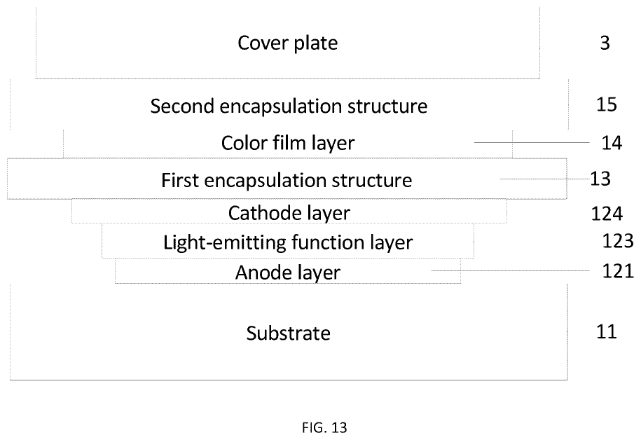

In specific implementation, in the above display panel provided by the embodiments of the present disclosure, as shown in FIG. 3, FIG. 9 and FIG. 13, the display substrate 1 includes: a substrate 11, a light-emitting device layer 12 between the substrate 11 and the first dam adhesive 2, a first encapsulation structure 13 between the light-emitting device layer 12 and the first dam adhesive 2, a color film layer 14 between the first encapsulation structure 13 and the first dam adhesive 2, and a second encapsulation structure 15 between the color film layer 14 and the first dam adhesive 2. Here, the combination of the first encapsulation structure 13 and the second encapsulation structure 15 can achieve effective encapsulation of the light-emitting device layer, effectively blocking the water vapor and oxygen, so as to realize the purpose of protecting the device and prolonging its life span. In addition, the second encapsulation structure 15 can flatten the color film layer 14 and the peripheral region BB, thus facilitating the production of subsequent film layers, facilitating the leveling of adhesive materials in the subsequent fit process of the cover plate 3, improving the fit quality of the cover plate 3, and playing a role in protecting the color film layer 14. When the second encapsulation structure 15 is set to include more than one layer, the second encapsulation structure 15 can provide the better protection. Optionally, the first encapsulation structure 13 includes a first encapsulation layer 131, a second encapsulation layer 132 and a third encapsulation layer 133 which are stacked. The first encapsulation layer 131 and the second encapsulation structure 15 are made of one or more combinations of an organic material and an inorganic material with good sealing characteristics; the inorganic material can be silicon oxide, silicon nitride, etc.; and the organic material can be an organic compound (OC) material. The material of the second encapsulation layer 132 can be an inorganic material, such as Al₂O₃, etc. The material of the third encapsulation layer 133 can be an inorganic material, such as SIN, etc.

In specific implementation, in the above display panel provided by the embodiments of the present disclosure, as shown in FIG. 3 and FIG. 9, the color film layer 14 includes: a plurality of color resists with different colors (e.g., a red color resist R, a green color resist G, and a blue color resist B) located in the display region AA and distributed in array, and at least one layer of shielding structure 141 with a planar structure in the peripheral region BB; and each layer of the shielding structure 141 is fabricated in synchronization with one of the plurality of color resists (a red color resist R, a green color resist G, and a blue color resist B). Optionally, the shielding structure 141 in the peripheral region BB may be formed by two layers of color resist materials having different colors, or may be formed by three layers of color resist materials having different colors. By forming the shielding structure 141 in the peripheral region BB, the proportion of reflected light from the metal wires of the peripheral region BB that is emitted from the light-emitting surface of the display panel may be reduced, so as to ensure the display uniformity of the peripheral region BB. Moreover, the first dam adhesive 2 located above the shielding structure 141 of the peripheral region BB can further block the reflected light of the peripheral region BB on the basis of the shielding structure 141 of the peripheral region BB, thereby further reducing the probability of the reflected light of the peripheral region BB being emitted from the light-emitting surface of the display panel. The embodiments of the present disclosure take two layers of the shielding structure 141 set in the peripheral region BB as an example, and each layer of the shielding structure 141 is synchronously fabricated with one of the red color resist R, the green color resist G and the blue color resist B. For example, in the present disclosure, the bottom layer of the shielding structure 141 is synchronously fabricated with the blue color resist B, and the top layer of the shielding structure 141 is synchronously fabricated with the red color resist R.

It should be noted that synchronous fabrication means that when the shielding structure 141 of the peripheral region BB has only two layers, it can be selected to be fabricated synchronously with the first two of the red color resist R, the green color resist G and the blue color resist B, or synchronously with the last two of them, or synchronously with the first and the third of them. When the shielding structure 141 of the peripheral region BB includes three layers, the layers of the shielding structure 141 are synchronously fabricated in accordance with the fabrication order of the display region AA.

Specifically, as shown in FIG. 3 and FIG. 9, an end of the shielding structure 141 of the peripheral region BB is flush with an edge of a side of the color film layer 14 close to shielding structure 141 of the peripheral region BB, allowing for the seamless connection between the shielding structure 141 of the peripheral region BB and the color film layer 14, being capable of covering the cathode ring region B2 closely adjacent to the display region AA, and preventing the reflection from the cathode ring region B2; and the seamless connection between the two also facilitates synchronous fabrication of color resists in the display region AA and the shielding structure 141 of the peripheral region BB. The other end of the shielding structure 141 of the peripheral region BB is approximately flush with an edge of a side of the metal wiring region B3 away from the display region AA, so that the shielding structure 141 of the peripheral region BB can cover above the metal wiring region B3, thereby preventing reflection from the metal wires of the metal wiring region B3, and reducing the reflectivity of the peripheral region BB.

In specific implementation, in the above display panel provided by the embodiments of the present disclosure, as shown in FIG. 3 and FIG. 9, the display substrate 1 further includes: a first planarization layer 16 between the first encapsulation structure 13 and the color film layer 14, a second planarization layer 17 between the second encapsulation structure 15 and the first dam adhesive 2, a third planarization layer 18 between the second planarization layer 17 and the first dam adhesive 2, a plurality of micro lenses 19 between the third planarization layer 18 and the first dam adhesive 2, and a protective layer 20 between the plurality of micro lenses 19 and the first dam adhesive 2. Optionally, the micro lenses 19 may be convex lenses, and the protective layer 20 may be an inorganic layer, such as silicon carbide (SiC), silicon-carbide nitride (SiCNx), SiNx, SiOx, and the like. The protective layer 20 may protect the color film layer 14 and the shielding structure 141 of the peripheral region BB, to reduce aging damage of the color film layer 14 and the shielding structure 141 of the peripheral region BB, and to increase the service life.

In specific implementation, in the above display panel provided by the embodiments of the present disclosure, as shown in FIG. 3 and FIG. 9, the substrate 11 is a silicon substrate, i.e., the display panel provided in the present disclosure is a silicon-based OLED micro display. Different from the conventional active-matrix organic light-emitting diode (AMOLED) device utilizing an amorphous silicon thin-film transistor, a microcrystalline silicon thin-film transistor, or a low-temperature polysilicon thin-film transistor as a backplane, the silicon-based OLED micro display apparatus uses a monocrystalline silicon chip as a substrate, and has a pixel size which is 1/10 of the traditional display apparatus, with the much higher fineness than the traditional device. The monocrystalline silicon chip using the existing mature integrated circuit CMOS process, which not only achieves the active addressing matrix of display pixels, but also achieves the drive control circuit of various functions such as a static random-access memory (SRAM) and a T-CON on the silicon chip, greatly reducing the device's external wiring, increasing reliability, and realize the lightweight. Moreover, the silicon-based OLED micro display apparatus has a simplified structure, reduces the cost, improves the display quality, and meets the special needs of different viewing angles, which can realize thin and light integrated design. The silicon-based AMOLED micro display has a broad market application space, especially suitable for application in helmet displays, stereoscopic display mirrors, and eye-type displays. Of course, the substrate 11 may also be a glass substrate or other flexible substrates.

In specific implementation, in the above display panel provided by the embodiments of the present disclosure, as shown in FIG. 3 and FIG. 9, the light-emitting device layer 12 includes an anode layer 121, a pixel defining layer 122, a light-emitting function layer 123, and a cathode layer 124 disposed in sequence; and the display substrate 1 further includes a driving circuit 10 for applying a driving voltage to the anode layer 121 and the cathode layer 124, and the driving circuit 10 may be independent of the substrate 11 or may be integrated in the substrate 11. The present disclosure is based on an example that the substrate 11 is a silicon substrate and the driving circuit 10 is integrated in the substrate 11.

Optionally, as shown in FIG. 3 and FIG. 9, the anode layer 121 is generally made of indium tin oxide (ITO), which has a high transmittance rate, a high work function, etc. The light-emitting function layer 123 is usually made of an organic material. By utilizing the light-emitting property of the organic material, the holes and electrons are excited to form excitons under the action of the voltage or the electric current to realize light emission. The cathode layer 124 may be a transparent structure, for example, it may be made by selecting one or more alloy materials from Mg/Ag.

Specifically, as shown in FIG. 3 and FIG. 9, each color resist of the color film layer is set to correspond to the light-emitting function layer to achieve a colored visual effect of the emitted light.

In specific implementation, in the above display panel provided by the embodiments of the present disclosure, as shown in FIG. 3 and FIG. 9, the driving circuit 10 is electrically connected with the anode layer 121 through a first metal layer 20 (e.g., tungsten) filled in a through-via penetrating the substrate 11, and the driving circuit 10 is electrically connected with the first adapter metal 40 through a second metal layer 30 (e.g., tungsten) filled in a through-via penetrating the substrate 11.

In specific implementation, in the above display panel provided by the embodiments of the present disclosure, as shown in FIG. 3 and FIG. 9, the cathode ring region B2 includes a cathode ring 50 which is disposed in the peripheral region BB and generally surround the display region AA, the cathode ring 50 is electrically connected with the cathode layer 124 via a third metal layer 60 and a lapping portion 70, the third metal layer 60 is tungsten filled in a through-via penetrating the substrate 11, the lapping portion 70 is disposed at the same layer as the anode layer 121, the cathode layer 124 is electrically connected with the lapping portion 70 via a through-via penetrating the pixel defining layer 122, and the cathode ring 50 is electrically connected with a second adapter metal 90 via a fourth metal layer 80 (e.g., tungsten) filled in a through-via penetrating the substrate 11, that is, the cathode layer 124 is electrically connected with the cathode ring 50 in the cathode ring region B2.

Specifically, the first adapter metal 40 and the second adapter metal 90 may be electrically connected with the driver integrated circuit (IC) or the flexible printed circuit (FPC) for providing electrical signals to the display panel.

Specifically, an anode layer 121, a light-emitting function layer 123 and a cathode layer 124 form a light-emitting device, and the pixel defining layer 122 is used for separating a plurality of light-emitting devices, i.e., the pixel defining layer 122 is used for defining a plurality of sub-pixel regions, with one light-emitting device provided for each sub-pixel region. The light-emitting device may be a self-luminous device such as an OLED or a quantum dot light-emitting device, i.e., the display panel may be an OLED display panel, or of course a display panel such as an LED.

Optionally, the cover plate may be a transparent cover plate made of a transparent glass material or other materials, and the present disclosure uses a mother glass with the high transmittance rate.

Optionally, the first dam adhesive and the second dam adhesive are transparent bonding adhesives, for example, may be the bonding adhesive layer formed by the optically clear adhesive (OCA); and the first dam adhesive and the second dam adhesive may also be the black adhesive layer. The first dam adhesive and the second dam adhesive are set as the black adhesive layer, which can play a role in preventing the reflected light from emitting from the light-emitting surface, thus improving the reflective phenomenon of the peripheral region.

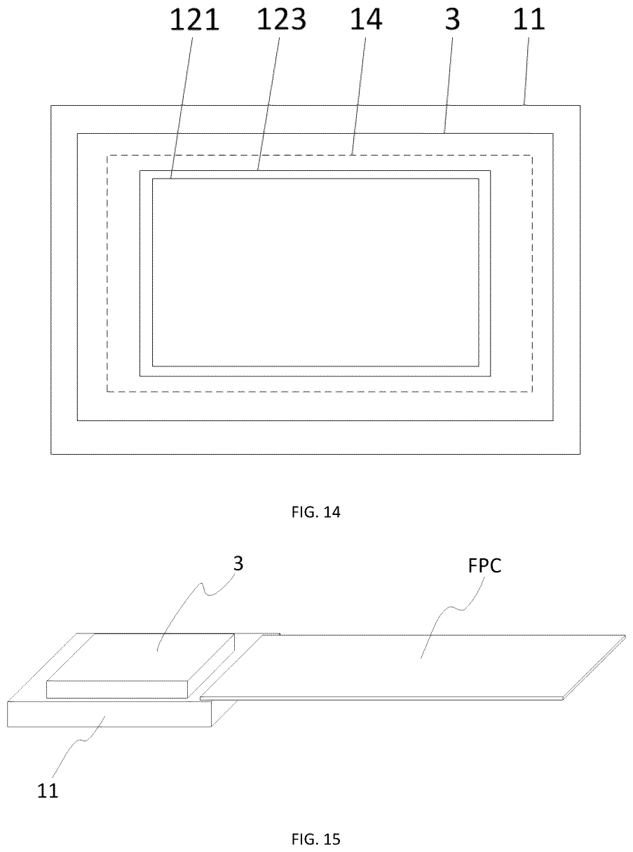

As shown in FIG. 14 and FIG. 15, FIG. 14 is a schematic planar view of some structures in FIG. 3 and FIG. 9, and FIG. 15 is a three-dimensional schematic diagram of some structures in the display panel. A size of the cover plate 3 is slightly larger than sizes of the light-emitting device layer 12 and the color film layer 14, and the size of the cover plate 3 is slightly smaller than the size of the substrate 11. A certain distance is left around the substrate 11 to realize the positioning and fixing of the silicon-based OLED visual effect module, here the light-emitting visual effect is realized by the light-emitting devices of the light-emitting device layer 12, and the driving circuit is integrated and designed in the substrate 11 to realize the voltage input driving of the light-emitting pixels. The FPC is connected on a side of the light-emitting device and the substrate 11, and the FPC realizes the transmission of the external signals by electrically connecting the display panel with the external circuit board.

As shown in FIG. 15, the FPC is mainly bound in the binding region B1, and the FPC is bound to the back of the display substrate 1 by bending, which facilitates the narrow bezel design of the display panel.

Based on the same inventive concept, the embodiments of the present disclosure also provide a display apparatus including the above display panel provided by the embodiments of the present disclosure. The principle of solving the problem in the display apparatus is similar to that of the aforementioned display panel, so the implementation of the display apparatus can refer to the implementation of the aforementioned display panel, and will not be repeated herein. The display apparatus may be a cell phone, a tablet computer, a television, a monitor, a laptop computer, a digital photo frame, a navigator, or any other product or component having a display function. Other essential components of the display apparatus should be understood by those of ordinary skill in the art, and are not be repeated herein, nor should they be taken as a limitation of the present disclosure.

The embodiments of the present disclosure provide a display panel and a display apparatus, and by forming a first outer circular arc of smooth transition between outer adjacent side edges of the first dam adhesive relative to the center of the display region, the curvature of the connection position between the first outer circular arc and the side edge is consistent with the curvature of the first outer circular arc, preventing the problem of static electricity accumulation due to the existence of a tip at the connection position between the first outer circular arc and the side edge. In addition, the first outer circular arc can increase the width of the corner, reduce stress of the corner, and improve the problem that the edge of the first dam adhesive is prone to peeling or whitening, thereby improving the stability of the display panel, enhancing the competitive advantage of the product, and increasing the yield of the product.

Obviously, those skilled in the art can make various modifications and variations to the present disclosure without departing from the spirit and scope of the present disclosure. Thus, if these modifications and variations of the present disclosure fall within the scope of the present claims and their technical equivalents, the present disclosure is intended to include these modifications and variations.

1. A display panel, comprising:
a display substrate, having a display region and a peripheral region around the display region;
a first dam adhesive on a side of a light-emitting surface of the display substrate; wherein the first dam adhesive is arranged in the peripheral region and surrounds the display region; wherein a first outer circular arc of smooth transition is formed between outer adjacent side edges of the first dam adhesive relative to a center of the display region; and
a cover plate on the side of the light-emitting surface of the display substrate, wherein the cover plate is bonded to the display substrate through the first dam adhesive.

2. The display panel according to claim 1, wherein a first inner circular arc of smooth transition is formed between inner adjacent side edges of the first dam adhesive relative to the center of the display region.

3. The display panel according to claim 2, wherein a curvature of the first outer circular arc is greater than a curvature of the first inner circular arc;
wherein an arc length of the first outer circular arc is greater than an arc length of the first inner circular arc.

4. (canceled)

5. The display panel according to claim 1, wherein a roughness of an inner surface of the first dam adhesive close to the display region is greater than a roughness of an outer surface of the first dam adhesive.

6. The display panel according to claim 1, wherein the peripheral region comprises a binding region at a side of the display region; and
an end of a side edge of the display region close to the binding region is substantially flush with an end of a flat side edge of the first dam adhesive close to the binding region.

7. The display panel according to claim 6, wherein the first dam adhesive comprises: a first structure close to the binding region, a second structure opposite to the first structure, and a third structure and a fourth structure connecting the first structure and the second structure and disposed opposite to each other; wherein,
a width of the first structure is greater than or equal to a width of the second structure, the width of the second structure is greater than a width of the third structure, and a width of the fourth structure is equal to the width of the third structure; and
the width of the first structure is within a range of 250 μm to 800 μm, the width of the second structure is within a range of 350 μm to 800 μm, and the width of the third structure is within a range of 200 μm to 350 μm.

8. (canceled)

9. The display panel according to claim 1, further comprising a second dam adhesive in the peripheral region, wherein the second dam adhesive is on a same layer as the first dam adhesive, and the second dam adhesive is spaced apart from and surrounds the first dam adhesive.

10. The display panel according to claim 9, wherein a second outer circular arc of smooth transition is formed between outer adjacent side edges of the second dam adhesive relative to the center of the display region;
wherein a second inner circular arc of smooth transition is formed between inner adjacent side edges of the second dam adhesive relative to the center of the display region.

11. (canceled)

12. The display panel according to claim 10, wherein a curvature of the second outer circular arc is greater than a curvature of the second inner circular arc, and the curvature of the second inner circular arc is greater than the curvature of the first outer circular arc;
wherein an arc length of the second outer circular arc is greater than an arc length of the second inner circular arc, and the arc length of the second inner circular arc is greater than the arc length of the first outer circular arc.

13. (canceled)

14. The display panel according to claim 9, wherein the second dam adhesive is at a side of the first dam adhesive away from the display region;
a width of the second dam adhesive is greater than the width of the first dam adhesive at same positions of the first dam adhesive and the second dam adhesive; and
the width of the first dam adhesive is greater than a distance between the first dam adhesive and the second dam adhesive;
wherein the width of the first dam adhesive is within a range of 350 μm to 550 μm, the width of the second dam adhesive is within a range of 400 μm to 600 μm, and the distance between the first dam adhesive and the second dam adhesive is within a range of 100 μm to 500 μm.

15. (canceled)

16. (canceled)

17. The display panel according to claim 14, wherein a distance between an outer edge of the second dam adhesive and an edge of the display substrate is within a range of 100 μm to 300 μm.

18. The display panel according to claim 14, wherein a first concave-convex structure is provided on an inner surface of the first dam adhesive close to the display region; and
a second concave-convex structure is provided on an inner surface of the second dam adhesive close to the display region.

19. The display panel according to claim 18, wherein a width of a concave position in the first concave-convex structure is greater than a width of a concave position in the second concave-convex structure, and a width of a convex position in the first concave-convex structure is greater than a width of a convex position in the second concave-convex structure;
wherein the width of the concave position and the width of the convex position in the first concave-convex structure are within a range of 50 μm to 80 μm, and the width of the concave position and the width of the convex position in the second concave-convex structure are within a range of 30 μm to 60 μm.

20. (canceled)

21. The display panel according to claim 19, further comprising:
a filler adhesive on an inner side of the first dam adhesive, wherein the filler adhesive is in direct contact with the first dam adhesive; and
a filler adhesive between the first dam adhesive and the second dam adhesive.

22. (canceled)

23. The display panel according to claim 14, wherein a height of the first dam adhesive is same as a height of the second dam adhesive.

24. The display panel according to claim 1, wherein the peripheral region further comprises a cathode ring region between the binding region and the display region, and an orthographic projection of the first dam adhesive on the display substrate covers the cathode ring region.

25. The display panel according to claim 1, wherein the display substrate comprises: a substrate, a light-emitting device layer between the substrate and a layer where the first dam adhesive is located, a first encapsulation structure between the light-emitting device layer and the layer where the first dam adhesive is located, a color film layer between the first encapsulation structure and the layer where the first dam adhesive is located, and a second encapsulation structure between the color film layer and the layer where the first dam adhesive is located;
wherein the color film layer comprises: a plurality of color resists of different colors disposed in the display region and distributed in an array, and at least one layer of shielding structures with a planar structure in the peripheral region; and each layer of the shielding structures is fabricated in synchronization with one of the plurality of color resists.

26. The display panel according to claim 25, wherein the display substrate further comprises: a first planarization layer between the first encapsulation structure and the color film layer, a second planarization layer between the second encapsulation structure and the layer where the first dam adhesive is located, a third planarization layer between the second planarization layer and the layer where the first dam adhesive is located, a plurality of micro lenses between the third planarization layer and the layer where the first dam adhesive is located, and a protective layer between the plurality of micro lenses and the layer where the first dam adhesive is located.

27. The display panel according to claim 26, wherein the substrate is a silicon substrate;
wherein the light-emitting device layer comprises an anode layer, a pixel defining layer, a light-emitting function layer, and a cathode layer disposed in sequence; and
the display substrate further comprises a driving circuit for applying a driving voltage to the anode layer and the cathode layer, wherein the driving circuit is independent of the substrate or the driving circuit is integrated in the substrate.

28. (canceled)

29. A display apparatus, comprising a display panel according to claim 1.
